(19) United States
(12) Patent Application Publication
(10) Pub. No.: US 2021/0248290 A1
(43) Pub. Date: Aug. 12, 2021

(54) MODELING, SIMULATION, AND ANALYSIS OF TRANSPORTATION SYSTEMS

(71) Applicant: HYPERLOOP TECHNOLOGIES, INC., Los Angeles, CA (US)

(72) Inventors: Jerome Wei, Hawthorne, CA (US); Walter Wang, Hacienda Heights, CA (US); Patryk Oleniuk, Los Angeles, CA (US); Leo Wong, Walnut, CA (US); Dapeng Zhang, West Covina, CA (US)

(21) Appl. No.: 17/168,870

(22) Filed: Feb. 5, 2021

Related U.S. Application Data
(60) Provisional application No. 62/971,607, filed on Feb. 7, 2020.

(51) Int. Cl. G06F 30/20; G06F 30/12; G06F 30/13

(52) U.S. Cl. CPC G06F 30/20; G06F 30/13; G06F 30/12

(57) ABSTRACT

A system for design, modeling, simulation, and analysis of transportation systems is described herein. The system may obtain a set of configuration data for a set of transportation systems. The system may generate a set of models for the set of transportation systems based on the set of configuration data. The system may simulate operations of the proposed transportation system and the one or more other transportation systems based the set of models. The system may also obtain a set of performance metrics for the set of transportation systems based on the simulation.

### CROSS-REFERENCE TO RELATED APPLICATIONS

This application claims the benefit of U.S. Provisional Patent Application No. 62/971,607, filed on Feb. 7, 2020. The disclosure of the above-referenced application is hereby incorporated by reference in its entirety.

### TECHNICAL FIELD

Aspects and implementations of the present disclosure relate to a modeling, simulation, and analysis of a mass transportation system and, in particular, modeling, simulation, and analysis of transportation system, such as a magnetic levitation (maglev) transportation system.

### BACKGROUND

Transportation systems may include multiple transportation lines and multiple transportation pods that travel along the various transportation lines. The transportation lines may be directed or directional routes that allow transportation pods (e.g., vehicles) to travel between different locations in the transportation system. For example, a transportation line may be similar to links, tracks, or rails that allow transportation pods to travel to different locations (e.g., stops, stations, etc.) within the transportation system. The transportation pods may be capsules, vehicles, cars, or some other type of device that may move from one location to another. For example, the transportation pods may be similar to trains, although the transportation pods may not travel on tracks. The transportation pods may transport various things between the stops in the transportation system 100. For example, the transportation pods may transport (e.g., move, convey, etc.) passengers or items, such as products, goods, freight, merchandise, payloads, shipments, packets, etc., between different stops in the transportation system.

One type of transportation system may be a magnetic levitation (maglev) transportation system. A maglev transportation system may transportation pods (e.g., maglev trains) that use a set of magnets to push the transportation pod up off of a track and a second set of magnets to propel the transportation pod along the track. The maglev transportation train system may use vacuum tubes, smaller vehicles/pods (e.g., when compared to trains), electric power, and magnetic levitation of the vehicles along the track.

### BRIEF DESCRIPTION OF THE DRAWINGS

Embodiments and implementations of the present disclosure will be understood more fully from the detailed description given below and from the accompanying drawings of various aspects and implementations of the disclosure, which, however, should not be taken to limit the disclosure to the specific embodiments or implementations, but are for explanation and understanding only.

FIG. 1 is a diagram illustrating example objectives for a transportation system in accordance with embodiments of the disclosure.

FIG. 2 is a block diagram that illustrates an example transportation system in accordance with embodiments of the disclosure.

FIG. 3 is an illustration of example applications for a transportation system in accordance with embodiments of the disclosure.

FIG. 4 is a block diagram illustrating a system architecture for designing transportation systems in accordance with embodiments of the disclosure.

FIG. 5 is a block diagram that illustrates an example transportation system design system, in accordance with some embodiments of the present disclosure.

FIG. 6 is a chart of an example of a transportation system model in accordance with embodiments of the disclosure.

FIG. 7 is table of examples of various performance metrics according to embodiments of the disclosure.

FIG. 8 is table illustrating other examples of performance metrics according to embodiments of the disclosure.

FIG. 9 is a flow diagram of a process of designing a transportation system in accordance with some embodiments.

FIG. 10 is a block diagram of an example computing device in accordance with some embodiments.

### DETAILED DESCRIPTION

A maglev train has inherent advantages (e.g., speed, scalability, etc.) over conventional mass transportation systems. Accordingly, a conventional mass transportation control system may not utilize and exploit the advantages of a maglev train system. Additionally, when developing/designing new mass transportation control systems, there is a challenge in demonstrating economic, performance, and safety of the control system for the general public, business analysts, regulatory bodies, and the scientific community.

Aspects and embodiments of the disclosure are directed to a designing, modeling, simulation, and analysis of a transportation systems, include a proposed transportation system. In embodiments, the proposed transportation system may be a magnetic levitation (maglev) train system. Aspects of the disclosure provide a quantitative approach towards modeling current and proposed transportation system. The approach includes understanding key performance metrics and developing a large scale simulations and analytics platform. The performance metrics and test results resulting from this approach may powerful evidence to regulatory and certification processes, and may accelerate adoption and deployment of current and proposed mass transportation control systems.

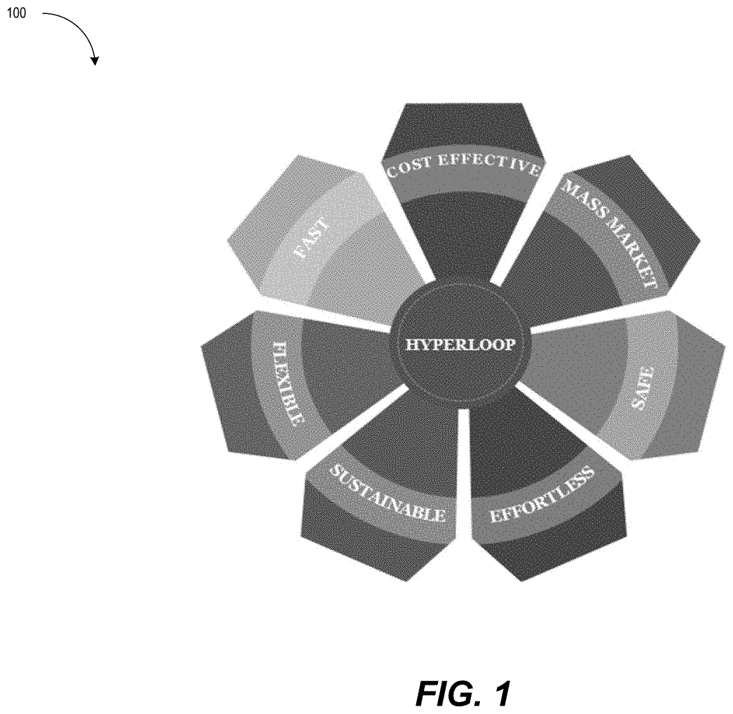

FIG. 1 is a diagram 100 illustrating example objectives for a transportation system in accordance with embodiments of the disclosure. Any combination of these objectives may influence the design of a transportation system and/or the control system for a transportation system, such as transportation system 100 illustrated in FIG. 1. One objective of a transportation system may be travel times. For example, the transportation system 100 may offer reduced, shorter, or at least comparable travel times to other transportation systems. Another objective may be to increase the capacity of the transportation system (e.g., the amount of passengers or parcels that may be transported). Increasing the capacity of the transportation system may allow the transportation system to operate more efficiently and provide better financial returns (e.g., may be more cost effective). The increased capacity may also allow the transportation system to be directed to the mass market (e.g., the general public). Directing the transportation system to the mass market (e.g., having a mass market transportation system) may allow for wider adoption and/or usage of the transportation system.

A further objective may be the autonomous operation of at least portions of the transportation system. For example, pods that operate autonomously may be safer than pods that are operated by humans (e.g., drivers, operators, etc.). One objective may be the reliability of the transportation system. For example, the more often a transportation system is able to transport passengers/cargo on time (e.g., based on a schedule), the more reliable the transportation system. The autonomous operations of the transportation system may also increase the reliability of the transportation system.

Another objective of the transportation system may be the ease of use for users (e.g., passengers, shipping companies, logistics companies, etc.) of the transportation system. For example, having direct lines to a destination/stop, or being able to connect/integrate with other transportation systems may be increase the ease of use of the transportation system. One objective of the transportation system may be to reduce the environmental impact of the transportation system. For example, reducing the carbon footprint, noise pollution, and/or direct emissions (e.g., is sustainable) created by the transportation system may be an objective.

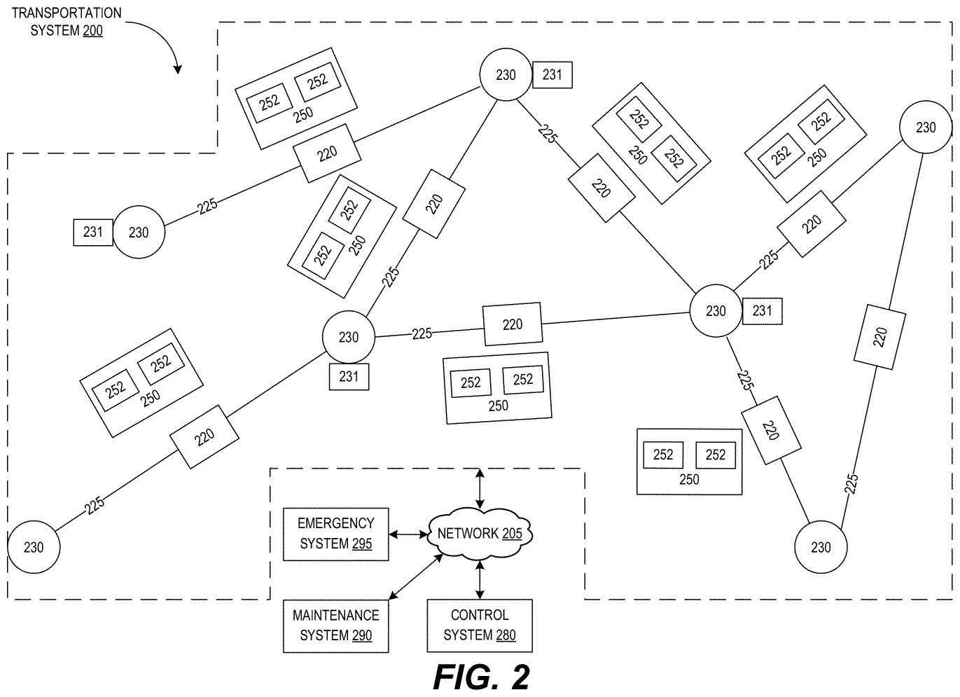

FIG. 2 is a block diagram that illustrates an example transportation system 200 in accordance with embodiments of the disclosure. The transportation system 200 includes transportation pods 220, transportation lines 225, and destinations 230. As discussed above, the transportation lines 225 may be directed or directional paths that allow transportation pods 220 (e.g., vehicles) to travel between the different destinations 230. For example, the transportation lines 225 may be similar to links, tracks, or rails that allow transportation pods 220 to travel to different locations (e.g., destinations 230) within the transportation system 220. In one embodiment, the transportation lines 225 may be tubes within which the transportation pods 220 may travel. For example, the transportation lines 225 may be vacuum sealed (or near vacuum sealed) tubes that include magnetic (e.g., electromagnetic) tracks. Different transportation lines 225 may be connected to each other via junctions between the transportation lines. A junction may be a location where two transportation lines converge or diverge. For example, a junction may allow a transportation pod 220 on a first transportation line to merge onto a second transportation line.

The transportation pods 220 may each be capsules, vehicles, cars, or some other type of device that may move from one location to another. For example, the transportation pods 220 may be similar to trains, although the transportation pods 220 may not travel on tracks. In one embodiment, transportation pods 220 may be a magnetic levitation (maglev) pod or capsule that travels along magnetic tracks located within a tube (e.g., a vacuum sealed or low air pressure tube). The transportation pods 220 may transport various things between the stops in the transportation system 200. For example, the transportation pods 220 may transport (e.g., move, convey, etc.) passengers between different stops in the transportation system 200. In another example, the transportation pods 220 may transport items, such as products, goods, freight, merchandise, payloads, shipments, packets, etc., between different stops in the transportation system. The transportation pods 220 may include multiple portions (e.g., multiple pods that are logically grouped or physically coupled together). The length of each of the transportation pods 220 may vary based on the needs or requirements of the transportation system 200 (e.g., may vary from less than ten meters to hundreds of meters). Transportation pods 220 may each include one or more of a light detection and ranging (LiDAR) device, a laser range finder, a camera (e.g., a video camera), a radio frequency device (e.g., a radar device), an ultrasonic sensor, etc., and/or other device that may be used for autonomous navigation and/or operation of the transportation pods 220.

The destinations 230 may be stops, stations, waypoints, etc., where passengers and/or cargo may be loaded onto the transportation pods 220. For example, the destinations 230 may be different cities, towns, metropolitan areas, etc., that are interconnected by the transportation lines 225. Although the present disclosure may refer to cities, towns, and/or metropolitan areas, the destinations 230 may be any location where a transportation 220 may stop (e.g., temporarily stop to load/unload passengers and/or cargo). For example, the destinations 230 may be stops (e.g., stations) within one city.

In some embodiments, a destination 230 may include additional transportation pods 220 that may be in a storage area, a depot, etc., of the destinations 230. These additional transportation pods 220 may be used to provide stable operations for the transportation system 200. For example, if there is a spike in a demand at a particular destination 230 (e.g., a sporting event ends, rush hour, etc.), the additional transportation pods 220 from the storage area of the destination 230 (or other destinations 230) may be added to one or more transportation lines to service the demand.

Some destinations 230 may include a transportation system interface 231. The transportation system interface 231 may be a kiosk, a portal, a stand, a computer system, etc., that allows a user (e.g., a passenger) to interface with the transportation system 200. For example, the transportation system interface 231 may allow a user to purchase a ticket, request that a transportation pod be directed to from a first destination 230 to a second destination 230, etc. The transportation system interface 231 may also be able to integrate with other systems, such as payment systems.

The infrastructure nodes 250 may be devices, systems, mechanisms, etc., that allow the transportation system 200 to detect, communicate with, and manage the transportation pods 220. The infrastructure nodes 250 may be positioned at various locations along the transportation lines 225. For example, there may be an infrastructure node 250 located every 20 meters, 50 meters, 200 meters, or some other appropriate distance along each of the transportation lines 225. The infrastructure nodes 250 may be placed at known or predetermined locations along the transportation lines 225 (e.g., the geographical locations of the infrastructure nodes 250 are known).

An infrastructure node 250 includes a sensor node 252. The sensor node 252 may include various devices, systems, mechanisms, etc., that allow the infrastructure node 250 to detect the location and/or speed of the transportation pods 220 as they travel through the transportation lines 225. For example, the sensor node 252 may include one or more of a radio frequency device (e.g., a radar device/system), a LiDAR device, a laser range finder, a camera (e.g., a video camera), an ultrasonic sensor, a Hall effect sensor, a presence sensor/detector (e.g., a device that detects the presence of a transportation pod 220), etc., that may be used to detect the speed of the transportation pods 220. Because the location of an infrastructure node 250 is known, the sensor node 252 allows an infrastructure node 250 to determine one or more of the speed and acceleration of a transportation pod at a certain point or location along a transportation line. The sensor node 252 may also be able to identify a transportation pod. For example, the sensor node 252 may include a radio-frequency identification (RFID) reader which may read an RFID tag located on a transportation pod. In another example, the sensor node 252 may determine an identifier for a transportation pod based on communications (e.g., messages) exchanged with the transportation pod via communication node 252.

An infrastructure node 250 also includes a communication node 252. The communication node 252 may allow the infrastructure node to communicate with one or more of a control system (e.g., a main control system, a command and control center, etc.), transportation pods 220, and other infrastructure nodes 250. For example, the communication node 252 may include a network interface (e.g., a wired network interface, a wireless network interface, etc.) that allows the infrastructure node 250 to communicate data (e.g., transmit and receive messages, packets, frames, etc.). Various communication protocols and technologies (e.g., cellular communications systems, Wi-Fi, Bluetooth, etc.) may be used by the communication node 252 to communicate data. The communication node 252 may communicate data about a transportation pod detected by a sensor node 252. For example, the transportation pod 220 passes an infrastructure node 250, the sensor node 252 may determine an identifier for the transportation pod 220 (e.g., a name, a serial number, a car number, etc.) and may determine the speed or acceleration of the transportation pod 220. The speed or acceleration of the transportation pod 220 may be referred to as movement information. The communication node 252 may transmit the movement information to other infrastructure nodes 250 or a control system, as discussed in more detail below.

The transportation system 200 also includes a control system 280. The control system 280 may control, manage, and monitor the operation of the transportation pods 220, as discussed in more detail below. The control system 280 may also provide planning functions/operations for the transportation pods 220. For example, the control system 280 may allow the transportation pods 220 to be re-routed or may be used to set one or more schedules for the transportation pods. The control system 280 may also be able to communicate with the infrastructure nodes 250 and the transportations pods 220 as discussed herein.

The transportation system 200 may further include infrastructure nodes 250, as discussed in more detail below. Each infrastructure node 250 may include a sensor node 252 and a communication node 252. In one embodiment, the transportation system 200 may be a closed transportation system where the addition and removal of transportation pods within the transportation system 200 is controlled (e.g., controlled or managed by the control system 280).

The transportation system 200 may also include a maintenance system 290. The maintenance system 290 may allow for the maintenance of the transportation pods 220 and/or the infrastructure nodes 250. For example, the maintenance system 290 may track which transportations pods 220 and/or infrastructure nodes 250 require maintenance (e.g., routing maintenance, repairs, etc.). The maintenance system 290 may schedule different transportations pods 220 for maintenance. The maintenance system 290 may also transmit request to personnel (e.g., repairmen, technicians) to coordinate the repair of the transportation pods 290 and/or the infrastructure nodes 250. In some embodiments, the maintenance system 290 may be part of the control system 280.

The transportation system 200 may also include an emergency system 295. The emergency system may manage, control, monitor, etc., emergency operations within the transportation system. For example, the transportation system 200 may reroute a transportation pod 220 to a nearest destination 230 if a passenger is experience a medical emergency (e.g., heart attack, difficulty breathing, etc.). The emergency system 295 may also coordinate with first responders and/or other medical services/systems to provide care to passengers. In another example, the emergency system 295 may track when emergency situations occur within the transportation system 230 (e.g., a stopped transportation pod 230 that is blocking a transportation line). The emergency system 295 may help coordinate the response to various emergency situations. For example, the emergency system 295 may coordinate the dispatch of repair personnel to fix a transportation line 225, a transportation pod 220, etc.

The control system 280 and the infrastructure nodes 250 may be interconnected or coupled to each other (e.g., communicatively coupled) via a network 205. The network 205 may carry communications (e.g., data, message, packets, frames, other appropriate types or formats of data, etc.) between the infrastructure nodes and the control system 280. The network 205 may be a public network (e.g., the Internet), a private network (e.g., a local area network (LAN) or wide area network (WAN)), or a combination thereof. In one embodiment, the network 205 may include a wired or a wireless infrastructure, which may be provided by one or more wireless communications systems, such as a wireless fidelity (Wi-Fi) hotspot connected with the network and/or a wireless carrier system that can be implemented using various data processing equipment, communication towers (e.g. cell towers), etc. The transportation pods 220 may also be connected to each other, the infrastructure nodes 250, and the control system 280 via the network 205.

Each transportation pod 220 may include a pod control module (not illustrated in FIG. 2). In one embodiment, the pod control module may control the operation of a transportation pod 220. For example, the pod control module may increase or decrease the speed of the transportation pod 220, may cause a transportation pod 220 to stop at a station (e.g., a destination 230), etc. In another example, the pod control module may cause a transportation pod 220 to merge from one transportation line 225 to another transportation line 225 at a junction between the two transportation lines 225.

The pod control module of a transportation pod 220 may communicate with other transportation pods 220 (e.g., other pod control modules). For example, the pod control module may transmit the current speed and location of a transportation pod 220 to another transportation pod 220. This may be referred to as vehicle-vehicle (V-V) communications. The pod control module may also communicate with the infrastructure nodes 250. For example, the pod control module may transmit the current speed and location of the transportation pod 220 to the in structure nodes 250. This may be referred to as vehicle-infrastructure (V-I) communications. The pod control module may also transmit and/or receive messages or other data with other transportation pods 220 via the infrastructure nodes 250 (e.g., the messages/data may be forwarded by the infrastructure nodes 250). This may be referred to as vehicle-infrastructure-vehicle (V-I-V) communications.

In some embodiments, the pod control module of a transportation pod 220 may operate in conjunction and/or coordination with the control system 280 to control the operation of the transportation pod 220. For example, the control system 280 may communicate with the pod control module of a transportation pod 220 and inform the pod control module of other transportation pods 220 in the vicinity of a junction. The pod control module may increase/decrease the speed of the transportation pod to allow the transportation pod to merge safely via the junction.

In other embodiments, the control system 280 may control the operation of the transportation pods 220. For example, the control system 280 may determine when a transportation pod 220 should increase/decrease speed, should merge from one transportation line 225 to another transportation line 225, etc. The control system 280 may transmit messages or instructions to the control modules of the transportation pods 220 to cause the transportation pods to increase speed, decrease speed, merge, etc.

Each of the pod control modules and the control system 280 may include one or more computing devices. A computing device may include hardware such as processing devices (e.g., processors, central processing units (CPUs), memory (e.g., random access memory (RAM), storage devices (e.g., hard-disk drive (HDD), solid-state drive (SSD), etc.), and other hardware devices (e.g., sound card, video card, etc.). A computing device may include any suitable type of device or machine that has a programmable processor including, for example, server computers, desktop computers, laptop computers, tablet computers, smartphones, etc. In some examples, a computing device may include a single machine or may include multiple interconnected machines (e.g., multiple servers configured in a cluster).

In one embodiment, the pod control modules and the control system 280 may also include one or more virtual machines (VMs). A VM may be a software implementation of a machine (e.g., a software implementation of a computing device) that includes its own operating system (referred to as a guest OS) and executes application programs, applications, software. A VM may execute on a hypervisor which executes on top of the OS for a computing device (referred to as a host OS). The hypervisor may also be referred to as a virtual machine monitor (VMM). The hypervisor may manage system resources, including access to hardware devices such as physical processing devices (e.g., processors, CPUs, etc.), physical memory (e.g., RAM), storage device (e.g., HDDs, SSDs), and/or other devices (e.g., sound cards, video cards, etc.). The hypervisor may also emulate the hardware (or other physical resources) which may be used by the VMs to execute software/applications.

In one embodiment, the pod control modules and the control system 280 may also include one or more containers. A container may be an isolated set of resources allocated to executing an application, software, and/or process independent from other applications, software, and/or processes. A container may execute on a container engine which executes on top of the OS for a computing device. The host OS (e.g., an OS of the computing device) may use namespaces to isolate the resources of the containers from each other. The container may share the kernel, libraries, and binaries of the host OS with other containers that are executing on the computing device. The container engine may allow different containers to share the host OS (e.g., the OS kernel, binaries, libraries, etc.) of a computing device. The container engine may also facilitate interactions between the container and the resources of the computing device.

In some embodiments, the design, layout, configuration, number of transportation pods, number of transportation lines, etc., in the transportation system 200 may be defined based on the various objectives (e.g., the objectives illustrated in FIG. 1). The design, layout, etc., of the transportation system 200 may also be defined based on a functional breakdown, requirements breakdown, and a product breakdown according to a standardized systems engineering process, such as an Architecture Analysis & Design Integrated Approach (ARCADIA). The ARCADIA process (or other engineering/design processes) may allow for the design of a mass transportation system that is economical (e.g., can generate a profit), safe, reliable, and/or efficient.

In some embodiments, the transportation system 200 may embody various core concepts. The first core concept may be to provided managed transit. Manage transit allows the transportation system 200 to provide robustness to contingencies and trip delays, flexibility to provide demand-responsive services, a highly automated multi-level trip planning and traffic management system is devised to ensure safe, performant transit. Each layer of systems within the transportation system 200 provides mechanisms for the coordination of movement at different timescales and levels of abstraction. The transportation pods 220 (e.g., autonomous pods) may have final control authority much like a pilot operating within the air traffic management (ATM) system.

The second core concept may be control authority. Similar to an aircraft pilot, the user and/or systems within a transportation pod 220 has ultimate control authority over the transportation pod 220. For example, the systems within the transportation pod 220 may perform the key functions to operate the transportation pod 220 and communicate with the control system 280 and/or other transportation pods 220. The transportation pod 220 may operate within the overall context of operations within the transportation system 200, including speed restrictions, current traffic conditions, etc. A transportation pod 220 may also coordinate its operations with the control system 280 (e.g., coordinate when to speed up, slow down, merge onto a junction, etc.).

A third core concept may be autonomous operation of various systems or components of the transportation system 230, such as the transportation pods 220. Autonomous operation may encompass the various operations, maneuvers, etc., that a transportation pod 200 may perform and the expected behavior during these operations/maneuvers. For example, autonomous operations may include merging onto or merging off of a junction, maintain a safe distance/separation between transportation pods 230, operating as a convoy of transportation pods, etc. Autonomous operation also encompass operations/maneuvers performed when unexpected events occur within the transportation system (e.g., when an obstruction in a transportation line 225 is detected).

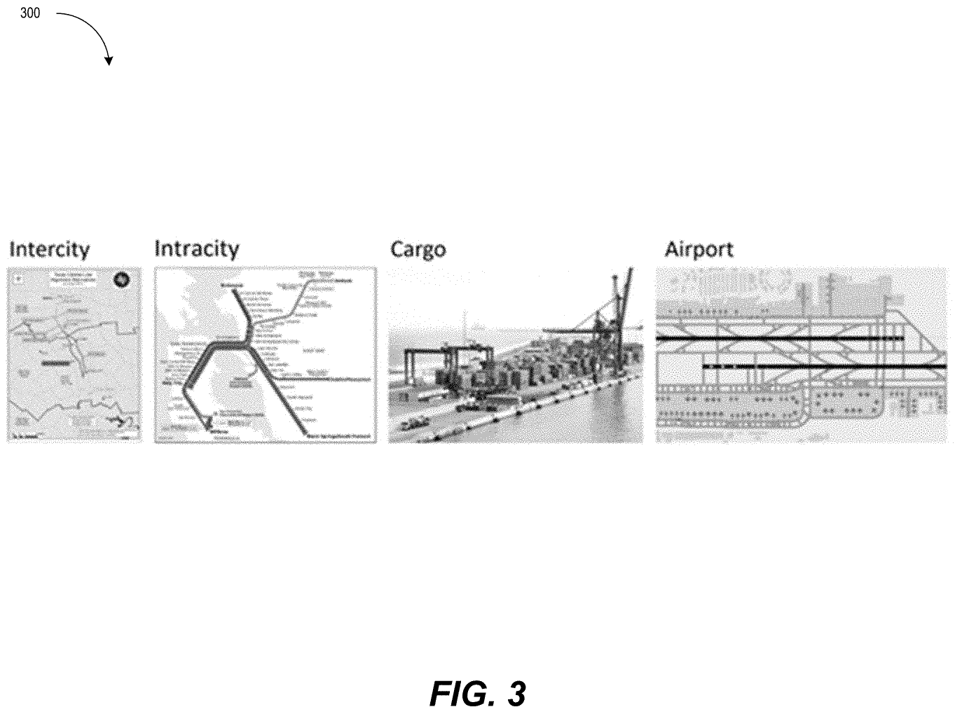

FIG. 3 is an illustration 300 of example applications for a transportation system in accordance with embodiments of the disclosure. Although examples provided herein may be given for a maglev transportation system (e.g., a hyperloop system), the embodiments, examples, implementations, etc., described herein of the disclosure may be utilized by any type of transportation systems.

In some embodiments, the transportation system (e.g., transportation system 200)) may be utilized for intercity transport of passengers and/or cargo. For example, the transportation system may be used to transport passengers and/or cargo between cities, counties, provinces, states, countries, etc. In other embodiments, the transportation system may be utilized as an intra-city transportation system. For example, the transportation system may be utilized as a metro, subway, etc., that may transport passengers and/or cargo between stops/destinations within a city.

In some embodiments, the transportation system may be utilized as a cargo transportation system. For example, the transportation system may be used to move cargo between various shipping ports, or from a shipping port to a delivery hub. In further embodiments, the transportation system may be utilized as a within another transportation system, such as an airport. For example, the transportation may transport passengers between terminals of an airport.

When designing transportation systems, various issues or challenges should be addressed/overcome to quantitatively validate the analysis and assumptions used for a proposed/existing transportation systems. One issue or challenge may be bridging the comparison cap between different transportation systems. When developing or designing a new/proposed transportation system, there may be no direct comparison to the new/proposed transportation system. For example, maglev trains (e.g., pods) are faster than conventional trains, more efficient, produce lower emissions than planes, and are demand-responsive and can be flexibly scheduled. Train system and airplane transportation systems are not demand responsive and cannot be flexibly scheduled (e.g., train/flight schedules cannot be changed based on user demand). Thus, comparing the benefits of a maglev transportation system versus an existing train/airplane transportation system may be difficult.

Another issue or challenge may be quantifying user value (e.g., quantifying the benefits to a passenger of the transportation system). To quantify the benefit and utility of the transportation to user, it may be useful to create a weighted evaluation and scoring model for each passenger trip across various metrics. These metrics can include trip duration, fare, comfort, convenience, etc., and can vary in importance between different markets and different use cases for the transportation system (e.g., intercity transport, intracity transport, cargo transport, etc.).

A further issue or challenge may be quantifying operator value (e.g., quantifying the benefits to the operator or owner of a transportation system). To quantify benefit and utility to an operator, it may be useful to create a weighted evaluation and scoring model for each passenger trip from an operator perspective. Metrics of interest (from the operator perspective) can include cost, performance, utilization rates, etc., and can vary in importance between different markets and different use cases for the transportation system.

Still another challenge or issue may be obtaining operational data for various transportation systems. For example, to provide direct comparisons between transportations systems, it may be useful to model service demand for a transportation system (e.g., for a certain layout or configuration) and to model performance of existing transportation.

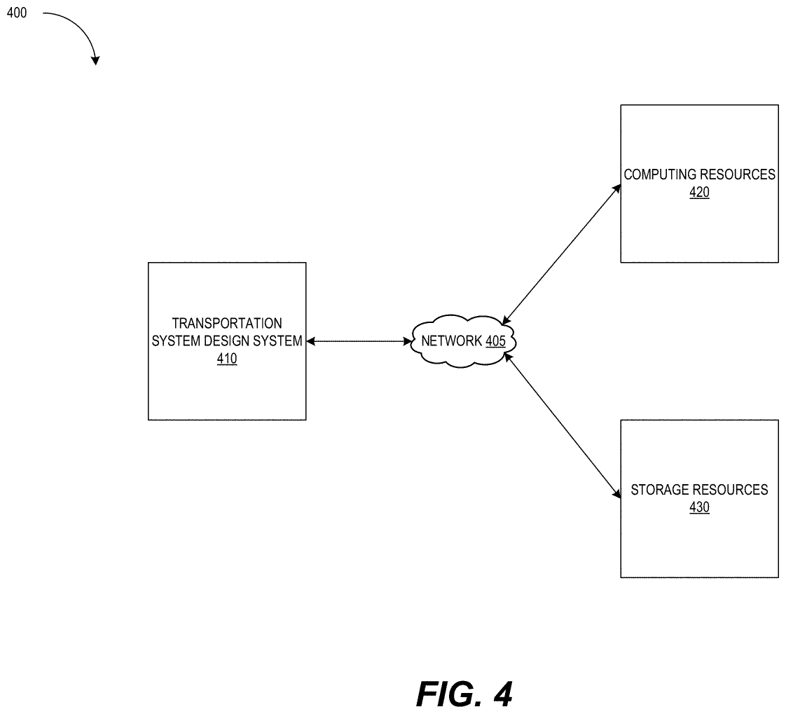

FIG. 4 is a block diagram illustrating a system architecture 400 for designing transportation systems in accordance with embodiments of the disclosure. The system architecture 400 may allow users to design transportations systems, simulate the operation of a transportation system, and analyze the operation and/or performance metrics of the transportation system.

The system architecture 400 includes a transportation system design system (TSDS) 410, computing resources 420, storage resources 430, and a network 405. The network 405 may interconnect the data vehicles 140, the TSDS 410, the computing resources 420, and/or the storage resources 430. The network 405 may be a public network (e.g., the internet), a private network (e.g., a local area network (LAN) or wide area network (WAN)), or a combination thereof. In one embodiment, network may include a wired or a wireless infrastructure, which may be provided by one or more wireless communications systems, such as a wireless fidelity (Wi-Fi) hotspot connected with the network, a cellular system, and/or a wireless carrier system that can be implemented using various data processing equipment, communication towers (e.g. cell towers), etc. The network 405 may carry communications (e.g., data, message, packets, frames, etc.) between the TSDS 410, the computing resources 420 and/or the storage resources 430.

The computing resources 420 may include computing devices which may include hardware such as processing devices (e.g., processors, central processing units (CPUs), processing cores), memory (e.g., random access memory (RAM), storage devices (e.g., hard-disk drive (HDD), solid-state drive (SSD), etc.), and other hardware devices (e.g., sound card, video card, etc.). The computing devices may comprise any suitable type of computing device or machine that has a programmable processor including, for example, server computers, desktop computers, rackmount servers, etc. In some examples, the computing devices may include a single machine or may include multiple interconnected machines (e.g., multiple servers configured in a cluster, cloud computing resources, etc.).

The computing resources 420 may also include virtual environments. In one embodiment, a virtual environment may be a virtual machine (VM) that may execute on a hypervisor which executes on top of the OS for a computing device. In another embodiment, a virtual environment may be a container that may execute on a container engine which executes on top of the OS for a computing device.

The storage resources 430 may include various different types of storage devices, such as hard disk drives (HDDs), solid state drives (SSD), hybrid drives, storage area networks, storage arrays, computing devices, etc. The storage resources 430 may also include cloud storage resources or platforms which allow for dynamic scaling of storage space.

Although the computing resources 420 and the storage resources 430 are illustrated separate from the TSDS 410, one or more of the computing resources 420 and the storage resources 430 may be part of the TSDS 410 in other embodiments. For example, the TSDS 410 may include one or more of the computing resources 420 and the storage resources 430.

In one embodiment, the TSDS 410 may be an application and data-source agnostic system. For example, the TSDS 410 may be able to work with a multitude of different applications, services, programs, etc., and may be able to uses data (e.g., configuration data) from various different sources of data. The TSDS 410 may provide a cloud-based infrastructure (e.g., computing resources 420 and/or storage resources 430) that may be tailored/customized for the design, simulation, and analysis of transportation systems. The TSDS 410 may support the various workflows, processes, operations, actions, tasks, etc., for designing/developing transportation systems. For example, the TSDS 410 may allow a user to design a transportation system, generate a model to simulate the operation of the transportation system, analyze performance metrics from the simulation, and update the model of the transportation system.

In one embodiment, data may be received, collected, ingested, etc., from various data sources by the TSDS 410. For example, configuration data for existing transportations systems (which may indicate the configuration of tracks, lines, flight paths, airplanes, trains, etc., within the existing transportation systems) may be received from different sources. In another example, existing performance metrics for existing transportations system may be received and/or processed.

In one embodiment, the TSDS 410 may manage the allocation and/or use of computing resources 420 (e.g., computing clusters, server computers, VMs, containers, etc.). The computing resources 420 may be used for executing models of proposed transportation systems and/or models of existing transportation systems. Executing the models of the proposed transportation systems and/or models of the existing transportation systems may allow the TSDS 410 to simulate the operation of the transportation systems.

In one embodiment, the TSDS 410 may also manage the allocation and/or use of storage resources 430. The storage resources 430 may store configuration data, performances metrics, models (e.g., different models or different versions of a model) of transportation systems, etc.

In one embodiment, the TSDS 410 may obtain a set of configuration data for a set of transportation systems. The set of transportation system may include a proposed transportation system (e.g., a maglev transportation system) and one or more other transportation systems. The configuration data may include various information/data about the configuration, layout, design, etc., of the transportation systems. For example, the configuration data may indicate the locations of different lines in the transportation system (e.g., the locations, height elevations, etc., of different paths/routes), maximum/minimum speeds for a line, characteristics/parameters of vehicles within the transportation system (e.g., the size, speed, acceleration, passenger capacity, etc., of different vehicles), etc. The configuration data may also include flight plans, schedules/timetables, etc., for a transportation system. The characteristics/parameters of the vehicles, the maximum/minimum speeds, etc., may also be referred to as operating parameters for the transportation system because they may define how different components of the transportation system operate.

In one embodiment, the proposed transportation system may not be an existing transportation system. For example, the proposed transportation system may be a new transportation system that may be built at a later time in a geographical location. The proposed transportation system may be a maglev transportation system. The one or more other transportation systems may be existing transportation systems. For example, the one or more other transportation systems may include an existing train transportation system in the same geographical location.

In one embodiment, the TSDS 410 may generate a set of models for the set of transportation systems based on the set of configuration data. Each model of the set of models may be used to simulate the operation of a respective transportation system. For example, a first model may be used to simulate the operation of the proposed transportation system (e.g., a maglev transportation system) and a second model may simulate the operation of an existing train system.

In one embodiment, the TSDS 410 may simulate the operations of the proposed transportation system and the one or more other transportation systems based the set of models. For example, the models may be executable models that may simulate the movement of passengers, vehicles, etc., within a transportation system when the models are executed. The TSDS 410 may simulate the operations of the transportation systems (e.g., execute the models) using the computing resources 420. For example, the TSDS 410 may provision VMs or other computing resources to execute the models. Executing the models or simulating the operations of transportation systems may be referred to as performing/executing an experiment.

In one embodiment, the TSDS 410 may obtain a set of performance metrics for the set of transportation systems based on the simulations (e.g., based on executing the models). The performance metrics may indicate various aspects of the performance or operation of the set of transportation systems. For example, the performance metrics may indicate an amount of energy used by a transportation system, the amount of passengers/cargo transported by the transportation system, wait times for passengers, distances traveled, etc.

In one embodiment, the TSDS 410 may analyze the set of performance metrics and a set of target performance metrics. Target performance metrics may be targets, goals, etc., for the proposed transportation system. For example, a target performance metric may indicate a desired amount of energy usage for the proposed transportation system, a desired cost for operating the proposed transportation system, etc.

In another embodiment, the TSDS 410 may compare the performance metrics of the proposed transportation system with the performance metrics of the one or more other (existing) transportation systems. For example, the energy usage of the proposed transportation system may be compared with the energy usage of the one or more other (existing) transportation systems.

In one embodiment, the TSDS 410 may provide an indication of the viability of the proposed transportation system based on one or more of the set of performance metrics and a set of target performance metrics. For example, if the energy usage of the proposed transportation system is less than the usage of an existing transportation system, the TSDS 410 may determine that the proposed transportation system is viable (e.g., is a viable alternative to the existing transportation system).

In one embodiment, the TSDS 410 may generate a control system for the proposed transportation system. The model for the proposed transportation system may use the control system to simulate the operation of the proposed transportation system. For example, the operation of the vehicles (e.g., transportation pods) may be controlled based on the control system. The control system may speed up a vehicle, slow down a vehicle, merge a vehicle onto a junction, cause the vehicle to stop at a destination (e.g., a station), etc. The control system may include both the control systems within a vehicle and a central control system for monitoring/managing the vehicles. For example, the control system may simulate or represent the control system 280 and/or the control system of a transportation pod 220 illustrated in FIG. 2.

In one embodiment, the control system generated by the TSDS 410 may provide a template for the final control system that may be used when the proposed transportation system is built/implemented. For example, the control system may serve as a base control system that may be modified to create the final control system for the when the proposed transportation system is built/implemented. This may simplify or streamline the process of designing and/or creating a control system because the control system generated by the TSDS 410 has already been testing during the simulation of the model of the proposed transportation system.

In one embodiment, the TSDS 410 may receive updated configuration data. New models may be generated and/or existing models may be updated based on the configuration data. For example, the model for a proposed transportation system may be updated to increase the vehicle speed or change the scheduling of different vehicles at different destinations based on the updated configuration data. In another example, the energy usage of a vehicle may be updated based on the updated configuration data.

In one embodiment, the TSDS 410 may simulate the operations of one or more transportation systems after updating the models for the one or more transportation systems. For example, after increasing the vehicle speed for a transportation system, the TSDS 410 may simulate the operation of the transportation system using the increased vehicle speed. This may allow a user to modify (e.g., tweak) different parameters of a transportation system to change the resulting performance metrics (e.g., improve the performance metrics) when the operation of the transportation system is simulated. This may also be referred to as re-executing a test/experiment with different parameters.

In one embodiment, the configuration data may indicate test parameters for simulating the operations of the proposed transportation system and/or one or more other transportation systems. For example, the configuration data may indicate that the vehicle speed is a test parameter that may be varied between different amounts between different simulations (e.g., the vehicle speed should be increased by 10 mph in each simulation). In another example, the configuration data may indicate that the number of passengers should be randomly varied in different simulations. This may allow the user to more easily execute different simulations of the transportation systems.

In one embodiment, the TSDS 410 may provide different views of the operations of the proposed transportation system and the one or more other transportation systems. For example, the TSDS 410 may provide a view that shows the movement of all of the vehicles and/or passengers within a simulation of a transportation system. The TSDS 410 may graphically indicate (e.g., using icons on a map) the movement of passengers and/or vehicles through the different lines of the transportation system.

In one embodiment, the TSDS 410 may provide different views of the operations of the simulation of a transportation system at different granularity levels. For example, the TSDS 410 may provide a view of the operation of a transportation system at a city level. The TSDS 410 may also allow a user to zoom in (e.g., increase the granularity) onto a particular vehicle to view the operation of that particular vehicles (e.g., which passengers used that vehicles, which route the vehicle travelled on, etc.).

In one embodiment, the TSDS 410 may provide various user interfaces to allow users to design, simulate, and analyze the transportation systems. For example, the TSDS 410 may provide a user interface that allows a user to create a model of the transportation system and/or update the model. The user input received via the user interface may be used to create/update the models. In another example, the TSDS 410 may provide a user interface that allows a user to generate a control system for a proposed transportation system. For example, the user interface may allow a user to indicate how the control system may interact with vehicles to control the operation of the vehicles. In a further example, the TSDS 410 may provide a user interface that allows a user to view the performance metrics of different transportation systems that were simulated by the TSDS 410. The TSDS 410 may provide graphs, tables, charts, etc., that may indicate various performance metrics (e.g., power used, distance travelled, etc.).

As discussed above, the TSDS 410 provides various functions, operations, capabilities, etc., that may be useful during the design, simulations, and/or analysis of transportation systems. The TSDS 410 allows users to create and update models of transportation systems (e.g., existing or proposed transportation systems). The TSDS 410 also allows users to simulate the operation of the transportation systems (e.g., execute the models). The TSDS 410 further allows the users to view performance metrics from the simulation of the transportation systems and compare those with other performance metrics and/or target metrics. The TSDS 410 allows users to compare a proposed transportation system with other transportation systems by comparing the operation and/or performance metrics of the different transportation systems. This allows the user to design a transportation system and determine the viability of the transportation system more quickly and/or easily. The performance metrics and/or results generated by the TSDS 410 may be provided to various entities (e.g., companies, corporations, government entities, etc.) for various regulatory and certification processes. This may accelerate adoption and deployment of the proposed transportation system as it allows the user/designer to provide evidence that the proposed transportation will be viable or competitive with other types of transportation systems.

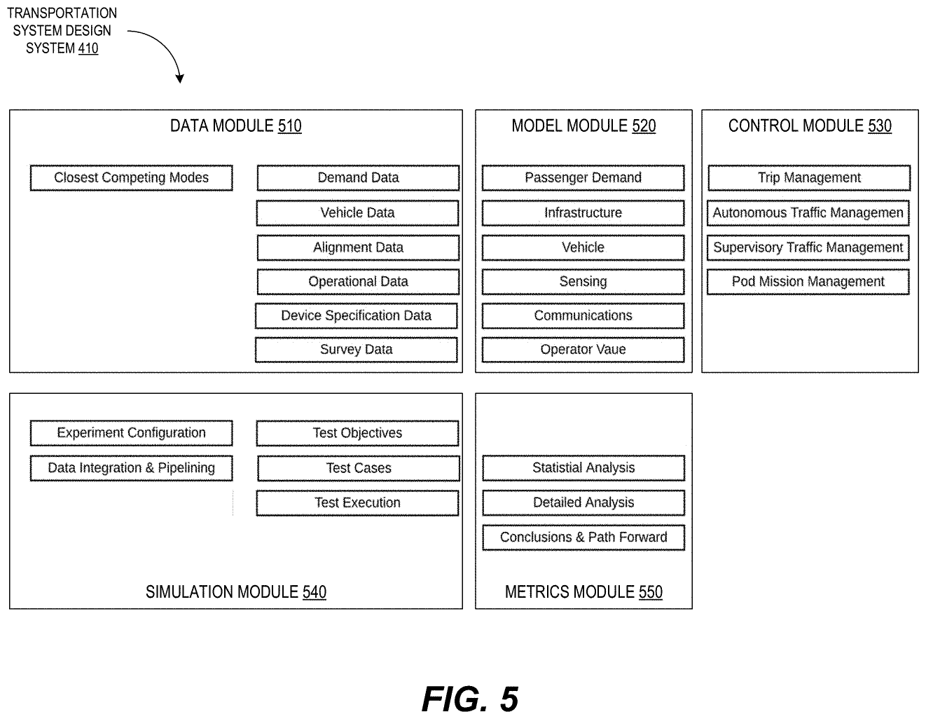

FIG. 5 is a block diagram that illustrates an example TSDS 410, in accordance with some embodiments of the present disclosure. The TSDS 410 includes a data module 510, a model module 520, a control module 530, a simulation module 540, and a metrics module 550. The data module 510, the model module 520, the control module 530, the simulation module 540, and the metrics module 550 may be interconnected via one or more or more networks (e.g., wired networks, wireless networks, etc.). The modules 510 through 550 may be implemented in software, hardware, firmware, or a combination thereof. For example, one or more of the modules 510 through 550 may be installed in persistent storage device, loaded into memory, and executed by one or more processors (not shown). In another example, one or more of the modules 510 through 550 may be processing devices, such as an application specific integrated circuit (ASIC), a field programmable gate array (FPGA), VMs, containers, etc. Some of modules 510 through 550 may be integrated together as an integrated component. In addition, some of the modules 510 through 550 may be located in different computing devices (e.g., different server computers).

In one embodiment, the data module 510 may identify existing transportation systems within a geographical area where the proposed transportation system should be located. For example, based on business requirements and analysis, the data module 510 may identify the transportation system that are comparable to the propose transportation system and that are used for the same purposed (e.g., passenger/cargo transport, intercity transport, etc.). The other transportation system may be identified based on distance, speed, fare, cost, and passenger experience, etc. Example transportation systems may include aviation, high speed rail, metro networks, bus service, etc.

In one embodiment, data module 510 may also collect operational or operating data for the other transportation systems. For example, data module 510 may obtain demand data which may indicate the usage of the transportation system over a period of time. The data module 510 may also obtain vehicle data which may indicate the specifications for different vehicles (e.g., size, weight, speed, energy usage, etc.). The data module 510 may also obtain alignment data which may indicate the locations/elevations of routes, elevations, etc., within the transportation systems. The data module 510 may also collect operational data which am include time tables, flight plans, hours of operation, etc. The transportation systems may also collect device specification data may provide information about other devices within the transportation system (e.g., communication nodes, track switching systems, etc.). The data module 510 may also collect survey data or information about the geographical area where the transportation systems are located.

In one embodiment, the model module 520 may be used to create models for the proposed transportation system and one or more other transportation systems (e.g., existing transportation systems). For example, the model module 520 may create a model to serve a particular customer demand. The model may also indicate the types and/or locations of infrastructure (e.g., track switching systems, bridges, tunnels, etc.) used by the transportation systems. The model may also indicate information about the vehicles (e.g., speed, max capacity, weight, etc.). The model may also indicate the types, capabilities, and/or locations of sensing and communication nodes in the transportation system. For example, the type of wireless communication (e.g., cellular, WiFi, etc.) used by a communication node or the type of sensor devices (e.g. laser sensor, radar sensor, etc.) used by a sensor node may be indicated by the model. The model may also indicate various operator values metrics that may be desired. For example, the model may indicate that a desired passenger throughput, or a desired energy usage, a desired profit margin, etc., for the transportation system.

In one embodiment, the control module 530 may be used to generate a control system for the proposed transportation system (e.g., a maglev transportation system). As discussed above, the control system may perform various functions. One function performed by the control system may be trip management. The control system may identify vehicles and/or routes for desired trip and may manage the operation of the vehicles throughout the trip. Another function performed by the control system may be autonomous traffic management. The control system may automatically control the operation of the vehicles to reduce traffic and to increase throughput in the transportation system. A further function may be supervisory traffic management. The control system may reroute vehicles along different paths based on different conditions that may arise, such as traffic, obstructions, malfunctioning vehicles, etc. The control system may also include the control system for a vehicle, such as a transportation pod. Each vehicle may perform at least some autonomous functions (e.g., speeding up, merging onto a junction, etc.) using an onboard control system that may communicate and operation in conjunction with the main control system of the transportation system.

In one embodiment, the simulation platform 540 may allow a user to configure or indicate test objectives/test cases for a model. For example, the simulation platform may allow a user to indicate operational parameters (e.g., throughput, speed, energy usage, etc.) that may be modified in different simulations (e.g., different runs/executions of a model). The simulation module 540 may automatically provision storage and/or processing resources to execute the various simulations (e.g., various experiments/tests). The simulations may be executed in parallel based on the amount of available processing resources.

In one embodiment, the metrics module 550 may allow a user to analyze the performance metrics or results of a simulation. For example, the metrics module 550 may analyze the results of a simulation and generate performance metrics for the simulation. The metrics module 550 may perform various analyses such as statistical analysis, on the results. The metrics module 550 may also compare performance metrics between different simulations to determine whether a proposed transportation system is viable, based on target performance metrics. The metrics module 550 may allow a user to to sort, search, filter, and compare simulation results across a large number of simulations.

The TSDS 410 may use REST APIs and REST endpoint definitions to allow users to execute simulations, configuration simulations, create models, modify models, etc. The TSDS 410 may also provide various user interface to allow users to create models, execute models, create a control system, and playback simulations of transportation systems. The TSDS 410 may also include various databases that may store the models, configuration data, operational data, any input files, test results, performance metrics, and/or other data used in the simulation of the transportation system. The TSDS 410 may automatically manage data flows between the different modules 510 through 550 during the process of designing, simulating, and analyzing transportation systems.

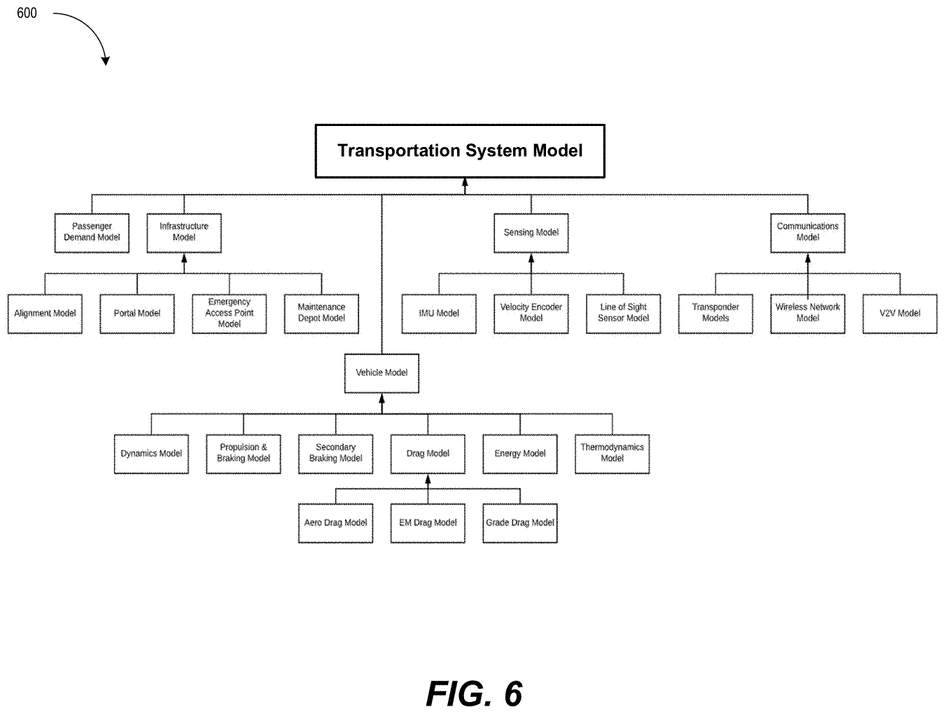

FIG. 6 is a chart 600 of an example of a transportation system model in accordance with embodiments of the disclosure. The transportation system model includes various other models, such as a passenger demand model, an infrastructure model, a sensing model, a communications model, and a vehicle model. These models may capture the latency, constraints, uncertainty, and failure effects of the represented system to enable testing of safety, robustness, and overall performance of the transportation system.

The passenger demand model may represent the number of passengers who are travelling in the transportation system, their origins/destinations, prices for each trip, etc. This information may be created by a user for a proposed transportation system and/or may be obtained via various APIs for existing transportation systems.

The infrastructure model may include information about the infrastructure for the transportation system. For example, the infrastructure model may include information about different routes, elevations along the route, access points, maintenance depots, storage depots (for backup vehicles), etc. The infrastructure model be a logical and/or spatially representative model of the physical operational structures in the transportation system.

The vehicle model may represent the various vehicles that are used in the transportation system. The vehicle model may indicate the speed, capacity, energy usage, aerodynamics, braking system, acceleration/deceleration, drag, thermodynamics, etc., of a vehicle.

The sensing model may represent sending nodes and/or other sensor devices that may be used by the transportation system. For example, the sensing model may represent various radar or laser ranging sensors that may be deployed along various routes of the transportation systems.

The communications model may represent the various communication nodes that may be located in the transportation system and/or vehicles. The communications model may indicate the type of communication used (e.g., a land line, wireless communications such as WiFi or cellular, etc.) that may be used by a communication node. The communications model may also indicate how data is communicated between the vehicles and/or the control system of the transportation system. For example, the communications model may indicate how and when V-I-V, V-V, or V-I communications are used.

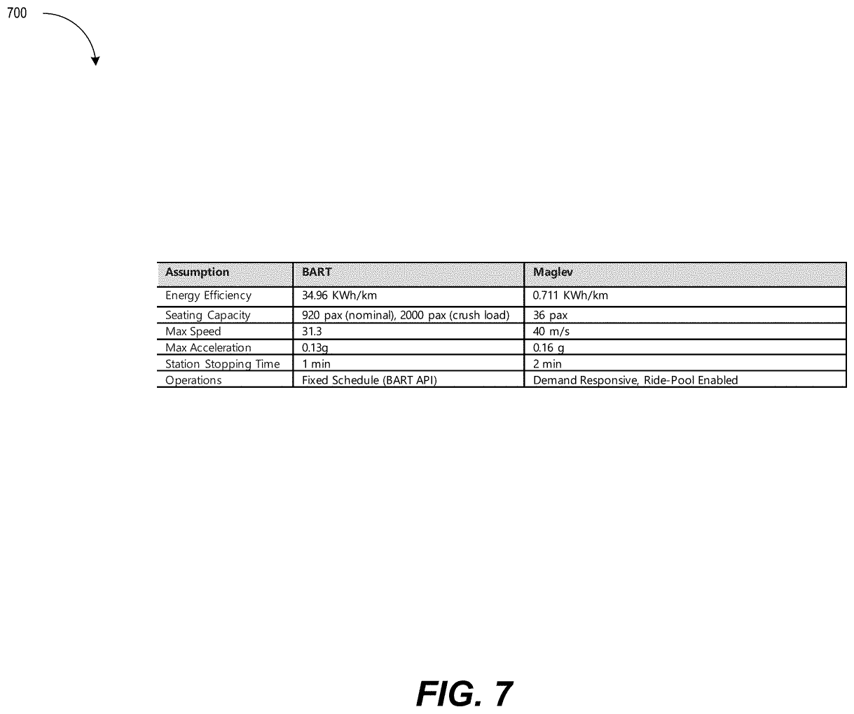

FIG. 7 is table 700 of examples of various performance metrics according to embodiments of the disclosure. The performance metrics may also be referred to as evaluation metrics. As illustrated table 700, two transportation systems are represented. The first transportation system may be the Bay Area Rapid Transit (BART) System. The BART system may be identified as a primary candidate due to the availability of high quality data for alignment, operations, and ridership, and high applicability for a maglev intercity metro transportation system. The second transportation system may be a proposed maglev transportation system. By modeling both transportation systems and their operations, performance metrics for both the transportation system may be obtained. The table 700 indicates the energy efficiency, seating capacity, max speed, max acceleration, stations topping time, and type of operation for the two transportation systems.

The BART API provides datasets that allow high fidelity modeling of the BART system, its operations, and ridership patterns. Routes in KML format capture the geospatial layout of linear infrastructure and stations. Service schedules or time tables capture actual movement of vehicles at any given time. Passenger trips include origin-destination and timestamps. Based on a model of average hourly ridership for each origin-destination pair derived from BART API passenger trips, a Poisson's distribution is sampled to generate passenger trips for a representative day of service. This passenger trip schedule is then allocated to departures in the BART API service schedule (for current service) and may be used to generate a demand responsive schedule with ride-pooling capability for the maglev transportation system.

To model operations in the maglev transportation system, model reduction is performed on high-fidelity physics based models of the maglev vehicle, linear infrastructure, and signaling systems and integrated into the maglev model. Routes for a maglev transportation system may be generated from the BART API available KML, and motion profiles for each origin-destination pair are created.

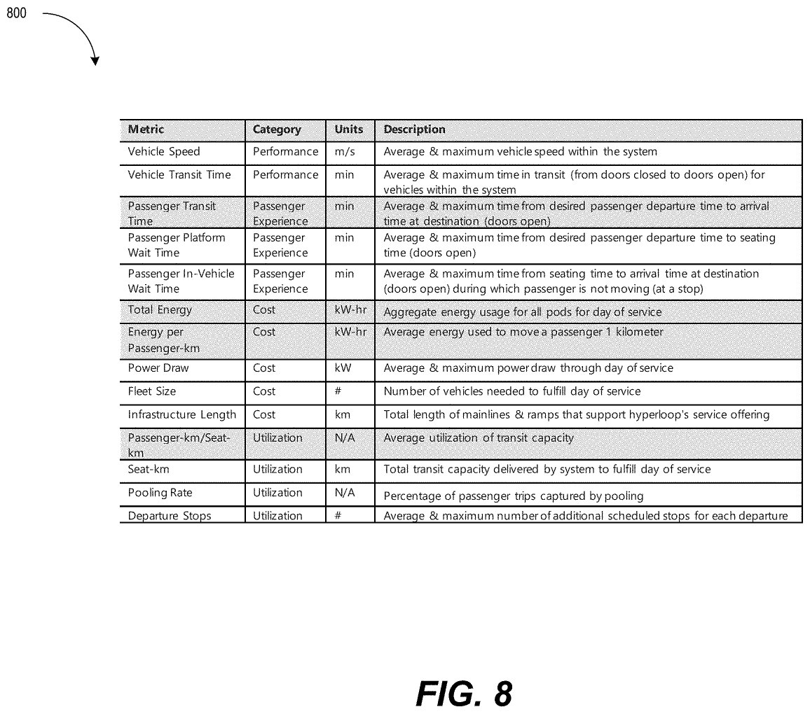

FIG. 8 is table 800 illustrating other examples of performance metrics according to embodiments of the disclosure. The performance metrics may be determined or measured during and/or after the simulation of a transportation system. For example, during or after the execution of a model for the transportation system, the results of the execution/simulation may be analyzed to determine the performance metrics.

The performance metrics include, but are not limited to, the vehicle speed, vehicle transit time, passenger transmit time, passenger platform wait time, passenger in vehicle weight time, total energy used, energy used per passenger, power draw, fleet size, the length of the infrastructure/routes, passenger

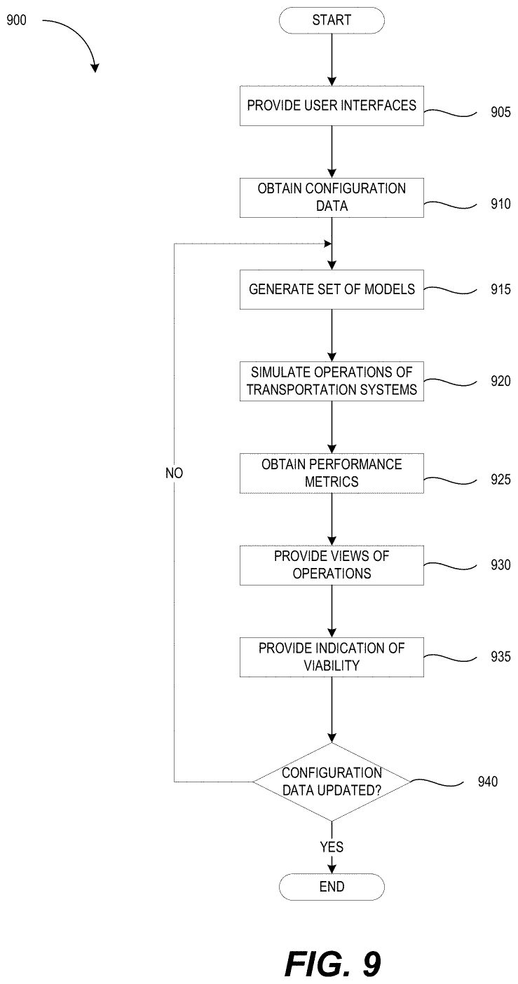

FIG. 9 is a flow diagram of a process 900 of designing a transportation system in accordance with some embodiments. Process 900 may be performed by processing logic that may comprise hardware (e.g., circuitry, dedicated logic, programmable logic, a processor, a processing device, a central processing unit (CPU), a system-on-chip (SoC), etc.), software (e.g., instructions running/executing on a processing device), firmware (e.g., microcode), or a combination thereof. In some embodiments, the process 900 may be performed by one or more of a control system and a computing device.

The process 900 begins at block 905, where the process 900 may optionally provide one or more user interfaces to a user. For example, a user interface for creating a model, generating a control system etc., may be provided to the user. At block 910, the process 900 may obtain configuration data for one or more transportation systems. At block 915, the process 900 may generate one or more models based on the configuration data. For example, the process 900 may generate a model for a proposed transportation system and one or more other models for one or more other transportation systems.

At block 920, the process 900 may simulate the operation of the transportation system. For example, the process 900 may execute the models to simulate the operations of the transportation systems. At block 925, the process 900 may analyze the results of the simulations and may obtain (e.g., generate) performance metrics for each of the transportation systems.

At block 930, the process 900 may optionally provide one or more views of the operations of the transportation systems. For example, the process 900 may allow the user to view the routes, number of passengers, etc., for each vehicles in the transportation system over a period of time. At block 935, the process 900 may provide an indication (e.g., a message) indicating the viability of the proposed transportation system. At block 940, the process may determine if any configuration data was update. If configuration data was updated, the process 900 may generate a new set of models (e.g., updated models) based on the updated configuration data at block 915.

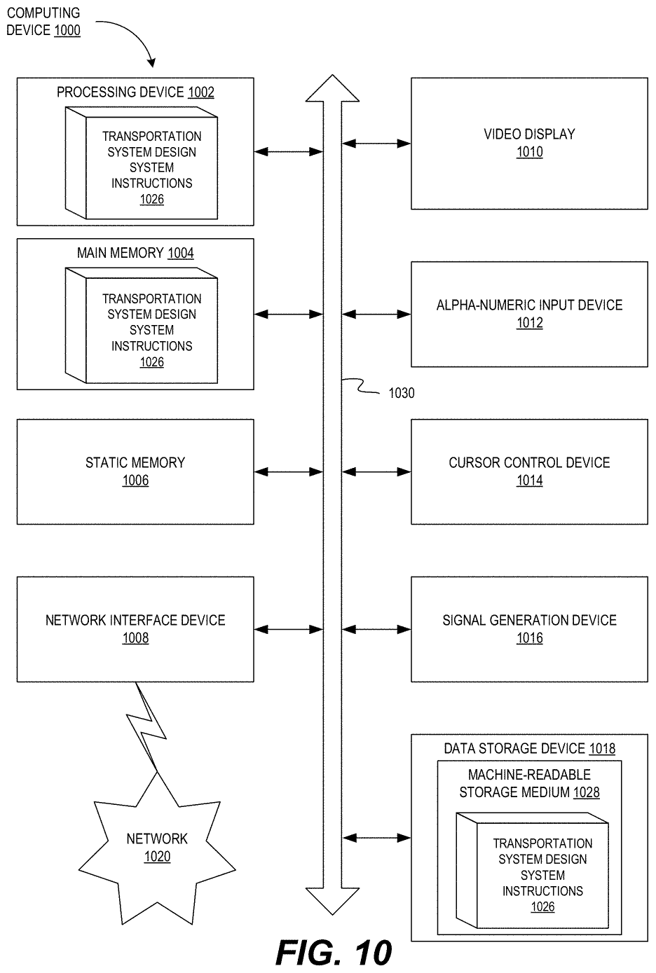

FIG. 10 is a block diagram of an example computing device 1000 that may perform one or more of the operations described herein, in accordance with some embodiments. Computing device 1000 may be connected to other computing devices in a LAN, an intranet, an extranet, and/or the Internet. The computing device may operate in the capacity of a server machine in client-server network environment or in the capacity of a client in a peer-to-peer network environment. The computing device may be provided by a personal computer (PC), a set-top box (STB), a server, a network router, switch or bridge, or any machine capable of executing a set of instructions (sequential or otherwise) that specify actions to be taken by that machine. Further, while only a single computing device is illustrated, the term “computing device” shall also be taken to include any collection of computing devices that individually or jointly execute a set (or multiple sets) of instructions to perform the methods discussed herein. In some embodiments, the computing device 1000 may be one or more of an access point and a packet forwarding component.

The example computing device 1000 may include a processing device (e.g., a general purpose processor, a PLD, etc.) 1002, a main memory 1004 (e.g., synchronous dynamic random access memory (DRAM), read-only memory (ROM)), a static memory 1006 (e.g., flash memory and a data storage device 1018), which may communicate with each other via a bus 1030.

Processing device 1002 may be provided by one or more general-purpose processing devices such as a microprocessor, central processing unit, or the like. In an illustrative example, processing device 1002 may comprise a complex instruction set computing (CISC) microprocessor, reduced instruction set computing (RISC) microprocessor, very long instruction word (VLIW) microprocessor, or a processor implementing other instruction sets or processors implementing a combination of instruction sets. Processing device 1002 may also comprise one or more special-purpose processing devices such as an application specific integrated circuit (ASIC), a field programmable gate array (FPGA), a digital signal processor (DSP), network processor, or the like. The processing device 1002 may be configured to execute the operations described herein, in accordance with one or more aspects of the present disclosure, for performing the operations and steps discussed herein.

Computing device 1000 may further include a network interface device 1008 which may communicate with a network 1020. The computing device 1000 also may include a video display unit 1010 (e.g., a liquid crystal display (LCD) or a cathode ray tube (CRT)), an alphanumeric input device 1012 (e.g., a keyboard), a cursor control device 1014 (e.g., a mouse) and an acoustic signal generation device 1016 (e.g., a speaker). In one embodiment, video display unit 1010, alphanumeric input device 1012, and cursor control device 1014 may be combined into a single component or device (e.g., an LCD touch screen).

Data storage device 1018 may include a computer-readable storage medium 1028 on which may be stored one or more sets of instructions, e.g., instructions for carrying out the operations described herein, in accordance with one or more aspects of the present disclosure. Instructions 1026 implementing one or more components/modules of a transportation system design system, may also reside, completely or at least partially, within main memory 1004 and/or within processing device 1002 during execution thereof by computing device 1000, main memory 1004 and processing device 1002 also constituting computer-readable media. The instructions may further be transmitted or received over a network 1020 via network interface device 1008.

While computer-readable storage medium 1028 is shown in an illustrative example to be a single medium, the term “computer-readable storage medium” should be taken to include a single medium or multiple media (e.g., a centralized or distributed database and/or associated caches and servers) that store the one or more sets of instructions. The term “computer-readable storage medium” shall also be taken to include any medium that is capable of storing, encoding or carrying a set of instructions for execution by the machine and that cause the machine to perform the methods described herein. The term “computer-readable storage medium” shall accordingly be taken to include, but not be limited to, solid-state memories, optical media and magnetic media.

Unless specifically stated otherwise, terms such as “requesting,” “determining,” “merging,” “activating,” “transmitting,” “receiving,” or the like, refer to actions and processes performed or implemented by computing devices that manipulates and transforms data represented as physical (electronic) quantities within the computing device's registers and memories into other data similarly represented as physical quantities within the computing device memories or registers or other such information storage, transmission or display devices. Also, the terms “first,” “second,” “third,” “fourth,” etc., as used herein are meant as labels to distinguish among different elements and may not necessarily have an ordinal meaning according to their numerical designation.

Examples described herein also relate to an apparatus for performing the operations described herein. This apparatus may be specially constructed for the required purposes, or it may comprise a general purpose computing device selectively programmed by a computer program stored in the computing device. Such a computer program may be stored in a computer-readable non-transitory storage medium.

The methods and illustrative examples described herein are not inherently related to any particular computer or other apparatus. Various general purpose systems may be used in accordance with the teachings described herein, or it may prove convenient to construct more specialized apparatus to perform the required method steps. The required structure for a variety of these systems will appear as set forth in the description above.

The above description is intended to be illustrative, and not restrictive. Although the present disclosure has been described with references to specific illustrative examples, it will be recognized that the present disclosure is not limited to the examples described. The scope of the disclosure should be determined with reference to the following claims, along with the full scope of equivalents to which the claims are entitled.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein, but may be modified within the scope and equivalents of the appended claims.

What is claimed is:

1. A method, comprising:
obtaining a set of configuration data for a set of transportation systems, wherein the set of transportation systems comprises a proposed transportation system and one or more other transportation systems.
generating a set of models for the set of transportation systems based on the set of configuration data, wherein each model of the set of models simulates operation of a respective transportation system of the set of transportation systems;
simulating operations of the proposed transportation system and the one or more other transportation systems based the set of models; and
obtaining a set of performance metrics for the set of transportation systems based on the simulation.

2. The method of claim 1, further comprising:
providing an indication of a viability of the proposed transportation system based on the set of performance metrics and a set of target performance metrics.

3. The method of claim 1, further comprising:
generating a control system for the proposed transportation system, wherein the control system is configured to control operation of the proposed transportation system.

4. The method of claim 3, wherein the operations of the proposed transportation system are simulated further based on the control system.

5. The method of claim 3, wherein the control system provides a template for implementing a final control system for the proposed transportation system.

6. The method of claim 1, wherein the proposed transportation system comprises a magnetic levitation transportation system.

7. The method of claim 1, wherein:
the proposed transportation system is located within a geographical area; and
the one or more other transportations systems comprise existing transportation systems that are located within the geographical area.

8. The method of claim 1, further comprising:
receiving updated configuration data; and
updating one or more models of the set of models based on the updated configuration data.

9. The method of claim 8, further comprising:
simulating operations of the proposed transportation system and the one or more updated models.

10. The method of claim 1, wherein the configuration data indicates operating parameters of the existing transportation system.

11. The method of claim 1, wherein the configuration data indicates test parameters for simulating operations of the proposed transportation system and the one or more other transportation systems.

12. The method of claim 1, further comprising:
providing one or more views of the operations of the proposed transportation system and the one or more other transportation systems.

13. The method of claim 12, wherein providing the view of the operations of the proposed transportation system and the one or more other transportation systems comprises:
providing views of the operations of the proposed transportation system and the one or more other transportation systems at different granularity levels.

14. The method of claim 1 further comprising:
providing a user interface for creating a model or updating the model.

15. The method of claim 1 further comprising:
providing a user interface for generating a control system for the proposed transportation system.

16. The method of claim 1, further comprising:
providing a user interface for viewing the set of performance metrics.

17. An apparatus, comprising:
a memory; and
a processing device coupled to the memory, the processing device configured to:
obtain a set of configuration data for a set of transportation systems, wherein the set of transportation systems comprises a proposed transportation system and one or more other transportation systems.
generate a set of models for the set of transportation systems based on the set of configuration data, wherein each model of the set of models simulates operation of a respective transportation system of the set of transportation systems;
simulate operations of the proposed transportation system and the one or more other transportation systems based the set of models; and
obtain a set of performance metrics for the set of transportation systems based on the simulation.

18. The apparatus of claim 1, wherein the processing device is further configured to:
provide an indication of a viability of the proposed transportation system based on the set of performance metrics and a set of target performance metrics.

19. The apparatus of claim 1, wherein the processing device is further configured to:
generate a control system for the proposed transportation system, wherein the control system is configured to control operation of the proposed transportation system.

20. A non-transitory computer readable medium having instructions stored thereon that, when executed by a processing device, cause the processing device to:
obtain a set of configuration data for a set of transportation systems, wherein the set of transportation systems comprises a proposed transportation system and one or more other transportation systems.
generate a set of models for the set of transportation systems based on the set of configuration data, wherein each model of the set of models simulates operation of a respective transportation system of the set of transportation systems;
simulate operations of the proposed transportation system and the one or more other transportation systems based the set of models; and
obtain a set of performance metrics for the set of transportation systems based on the simulation.
